(19) United States
(12) Patent Application Publication
(10) Pub. No.: US 2024/0339576 A1
(43) Pub. Date: Oct. 10, 2024

(54) CIRCUIT BOARD AND DISPLAY DEVICE INCLUDING SAME

(71) Applicant: Samsung Display Co., Ltd., Yongin-si (KR)

(72) Inventors: MYONGHOON ROH, Yongin-si (KR); EUI JEONG KANG, Yongin-si (KR); HANHO PARK, Yongin-si (KR); DAEGEUN LEE, Yongin-si (KR); JOONGMOK LEE, Yongin-si (KR); EUNJEONG JEON, Yongin-si (KR)

(21) Appl. No.: 18/417,997

(22) Filed: Jan. 19, 2024

(30) Foreign Application Priority Data
Apr. 6, 2023 (KR) 10-2023-0045650

(51) Int. Cl. H01L 33/62; H01L 25/075

(52) U.S. Cl. CPC H01L 33/62; H01L 25/0753

(57) ABSTRACT

A circuit board includes a plurality of insulating layers, at least one conductive layer disposed between the plurality of insulating layers, a connection pad disposed under the conductive layer, a signal line disposed under the conductive layer and electrically connected to the connection pad, and a protective layer disposed under the conductive layer and having a lower surface positioned in a same plane as a lower surface of the connection pad.

This application claims priority to Korean Patent Application No. 10-2023-0045650, filed on Apr. 6, 2023, and all the benefits accruing therefrom under 35 U.S.C. § 119, the content of which in its entirety is herein incorporated by reference.

### BACKGROUND

### 1. Technical Field

This invention relates generally to a circuit board, and more particularly, to a circuit board and a display device including the circuit board.

### 2. Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

Meanwhile, the display device includes a display panel and a circuit board, wherein the display panel may include a pad area in which pad electrodes for receiving various signals, voltages, and the like from the outside are disposed. The circuit board may be coupled to the pad area to provide various signals and voltages necessary for driving the display panel to the display panel.

### SUMMARY

Embodiments provide a circuit board capable of reducing compression defect.

Embodiments provide a display device including the circuit board.

A circuit board according to embodiments of the invention includes a plurality of insulating layers, at least one conductive layer disposed between the plurality of insulating layers, a connection pad disposed under the conductive layer, a signal line disposed under the conductive layer and electrically connected to the connection pad, and a protective layer disposed under the conductive layer and having a lower surface positioned in a same plane as a lower surface of the connection pad.

In an embodiment, a thickness of the protective layer may be equal to a thickness of the connection pad.

In an embodiment, the conductive layer may include a first conductive layer disposed on the connection pad and the signal line and a second conductive layer disposed on the first conductive layer.

In an embodiment, the plurality of insulating layers may include a first insulating layer disposed between the first conductive layer and the connection pad, wherein the connection pad may be connected to the first conductive layer through at least one first contact hole penetrating the first insulating layer, and wherein the signal line may be connected to the first conductive layer through at least one second contact hole penetrating the first insulating layer.

In an embodiment, the first conductive layer may include a plurality of conductive patterns each extending in a first direction and spaced apart from each other in a second direction crossing the first direction, wherein the second conductive layer may have a plate shape.

In an embodiment, the connection pad and the signal line may be spaced apart from each other in the first direction, wherein each of the conductive patterns may overlap the connection pad and the signal line in a plan view.

In an embodiment, each of the first contact hole and the second contact hole may have a polygonal cross-sectional shape.

In an embodiment, the conductive layer may include a first conductive layer disposed on the connection pad and the signal line, a second conductive layer disposed on the first conductive layer, and a third conductive layer disposed on the second conductive layer.

In an embodiment, the plurality of insulating layers may include a first insulating layer disposed between the first conductive layer and the connection pad and a second insulating layer disposed on the first insulating layer, wherein the connection pad may be connected to the first conductive layer through at least one first contact hole penetrating the first insulating layer, the signal line may be connected to the first conductive layer through at least one second contact hole penetrating the first insulating layer, the second conductive layer may be connected to the first conductive layer through at least one third contact hole and at least one fourth contact hole penetrating the second insulating layer.

In an embodiment, each of the first and second conductive layers may include a plurality of conductive patterns each extending in a first direction and spaced apart from each other in a second direction crossing the first direction, wherein the third conductive layer may have a plate shape.

In an embodiment, the signal line may be disposed on the protective layer and the signal line may be integral with the connection pad.

In an embodiment, a thickness of a part of the signal line overlapping the protective layer may be smaller than a thickness of the connection pad.

In an embodiment, the protective layer may include a solder resist.

In an embodiment, each of the connection pad, the signal line, and the conductive layer may include copper (Cu).

A display device according to embodiments of the invention includes a substrate including a display area in which a plurality of pixels are arranged and a pad area spaced apart from one side of the display area, a pad electrode disposed in the pad area on the substrate, and a circuit board including a plurality of insulating layers, at least one conductive layer disposed between the plurality of insulating layers, a connection pad disposed under the conductive layer and connected to the pad electrode through an adhesive layer, a signal line disposed under the conductive layer and electrically connected to the connection pad, and a protective layer disposed under the conductive layer, overlapping at least a part of the pad area, and having a lower surface positioned in a same plane as a lower surface of the connection pad.

In an embodiment, a thickness of the protective layer may be equal to a thickness of the connection pad.

In an embodiment, the conductive layer may include a first conductive layer disposed on the connection pad and the signal line and a second conductive layer disposed on the first conductive layer.

In an embodiment, the plurality of insulating layers may include a first insulating layer disposed between the first conductive layer and the connection pad, wherein the connection pad may be connected to the first conductive layer through at least one first contact hole penetrating the first insulating layer, and the signal line may be connected to the first conductive layer through at least one second contact hole penetrating the first insulating layer.

In an embodiment, the first conductive layer may include a plurality of conductive patterns each extending in a first direction and spaced apart from each other in a second direction crossing the first direction, the second conductive layer may have a plate shape, the connection pad and the signal line may be spaced apart from each other in the first direction, and each of the conductive patterns may overlap the connection pad and the signal line in a plan view.

In an embodiment, the signal line may be disposed on the protective layer and may be integral with the connection pad, and wherein a thickness of a part of the signal line overlapping the protective layer may be smaller than a thickness of the connection pad.

A circuit board according to an embodiment may include at least one conductive layer, a connection pad disposed under the conductive layer, a signal line disposed under the conductive layer and electrically connected to the connection pad, and a protective layer disposed under the conductive layer and having a lower surface positioned in the same plane as a lower surface of the connection pad.

When the circuit board is coupled with a pad electrode disposed in a pad area on a substrate of a display panel, the protective layer of the circuit board may partially overlap the pad area. Accordingly, a compression defect due to lifting between the circuit board and the display panel can be reduced.

### BRIEF DESCRIPTION OF THE DRAWINGS

Illustrative, non-limiting embodiments will be more clearly understood from the following detailed description in conjunction with the accompanying drawings.

FIG. 1 is a plan view of a display device, according to an embodiment.

FIG. 2 is a schematic diagram illustrating a circuit for one pixel of the display device of FIG. 1, according to an embodiment.

FIG. 3 is an enlarged plan view of area A of FIG. 1, according to an embodiment.

FIG. 4 is a cross-sectional view taken along line I-I′ of area A of FIG. 3, according to an embodiment.

FIG. 5 is a cross-sectional view illustrating an examples of a shape of each of a first contact hole and a second contact hole of FIG. 4, according to an embodiment.

FIG. 6 is a cross-sectional view illustrating an examples of a shape of each of a first contact hole and a second contact hole of FIG. 4, according to an embodiment.

FIG. 7 is a cross-sectional view illustrating an examples of a shape of each of a first contact hole and a second contact hole of FIG. 4, according to an embodiment.

FIG. 8 is a cross-sectional view illustrating an examples of a shape of each of a first contact hole and a second contact hole of FIG. 4, according to an embodiment.

FIG. 9 is an enlarged cross-sectional view of area B of FIG. 4, according to an embodiment.

FIG. 10 is an enlarged plan view of area A of FIG. 1, according to another embodiment.

FIG. 11 is a cross-sectional view illustrating a cross section taken along line II-II′ of FIG. 10, according to an embodiment.

FIG. 12 is a cross-sectional view illustrating a cross section taken along line II-II′ of FIG. 10, according to another embodiment.

FIG. 13 is an enlarged plan view of area A of FIG. 1, according to another embodiment.

FIG. 14 is a cross-sectional view illustrating a cross section taken along line III-III′ of FIG. 13, according to an embodiment.

FIG. 15 is a cross-sectional view illustrating a cross section taken along line III-III′ of FIG. 13, according to another embodiment.

FIG. 16 is an enlarged plan view of area A of FIG. 1, according to another embodiment.

FIG. 17 is a cross-sectional view illustrating a cross section taken along line IV-IV′ of FIG. 16, according to an embodiment.

FIG. 18 is a cross-sectional view illustrating a cross section taken along line IV-IV′ of FIG. 16, according to another embodiment.

FIG. 19 is a block diagram illustrating an electronic device including the display device of FIG. 1, according to an embodiment.

FIG. 20 is a perspective view illustrating the electronic device of FIG. 19 implemented as a television, according to an embodiment.

FIG. 21 is a perspective view illustrating the electronic device of FIG. 19 implemented as a smartphone, according to another embodiment.

### DETAILED DESCRIPTION OF THE EMBODIMENTS

Hereinafter, a circuit board and a display device including the same according to embodiment of the invention will be explained in detail with reference to the accompanying drawings, in which various embodiments are shown. The same reference numerals are used for the same components in the drawings, and redundant descriptions of the same components will be omitted. Additionally, this invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element (or a region, a layer, a portion, and/or the like) is referred to as being related to another such as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

The term “and/or,” includes all combinations of one or more of which associated configurations may define.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, and/or the like may be used to describe the relationships of the elements illustrated in the drawings. These terms have relative concepts and are described on the basis of the directions indicated in the drawings.

It will be further understood that the terms “comprise”, “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof. As used herein, being “disposed directly on” may mean that there is no additional layer, film, region, plate, and/or the like between a part and another part such as a layer, a film, a region, a plate, and/or the like. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

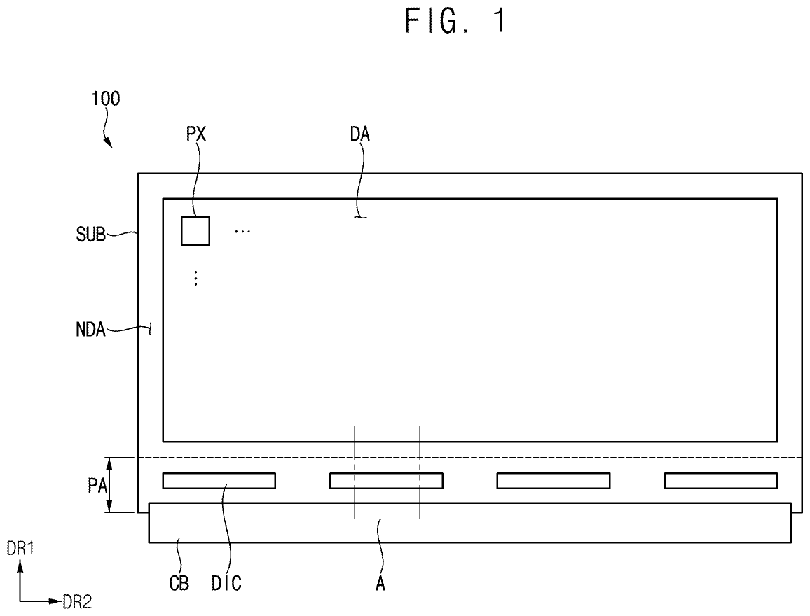

FIG. 1 is a plan view illustrating a display device according to an embodiment of the invention.

Referring to FIG. 1, a display device 100 according to an embodiment may include a substrate SUB, driving integrated circuits DIC, and a circuit board CB.

In an embodiment, the substrate SUB may include a display area DA and a non-display area NDA. The display area DA may be an area capable of displaying an image by generating light or adjusting transmittance of light provided from an external light source. The non-display area NDA may be an area not displaying an image.

In an embodiment, a plurality of pixels PX may be disposed in the display area DA. The plurality of pixels PX may be arranged in a matrix form along a first direction DR1 and a second direction DR2 crossing the first direction DR1. Each of the plurality of pixels PX may emit light. As each of the plurality of pixels PX emits light. The display area DA may display an image.

In an embodiment, lines connected to the plurality of pixels PX may be further disposed in the display area DA. For example, the lines may include a data signal line, a gate signal line, and/or a power line.

In an embodiment, the non-display area NDA may be positioned around the display area DA. For example, the non-display area NDA may surround at least a part of the display area DA. A driver may be disposed in the non-display area NDA. The driver may provide signals and/or voltages to the plurality of pixels PX. For example, the driver may include a gate driver, a light emitting driver, a power voltage generator, a timing controller, and the like.

In an embodiment, the non-display area NDA may include a pad area PA. The pad area PA may be spaced apart from one side of the display area DA in a direction opposite to the first direction DR1. For example, the pad area PA may have a shape extending in the second direction DR2.

In an embodiment, each of the driving integrated circuits DIC may be disposed in the pad area PA on the substrate SUB. The driving integrated circuits DIC may be disposed to be spaced apart from each other in the second direction DR2. Each of the driving integrated circuits DIC may convert a digital data signal among driving signals into an analog data signal and provide the converted analog data signal to the plurality of pixels PX. For example, each of the driving integrated circuits DIC may be a data driver.

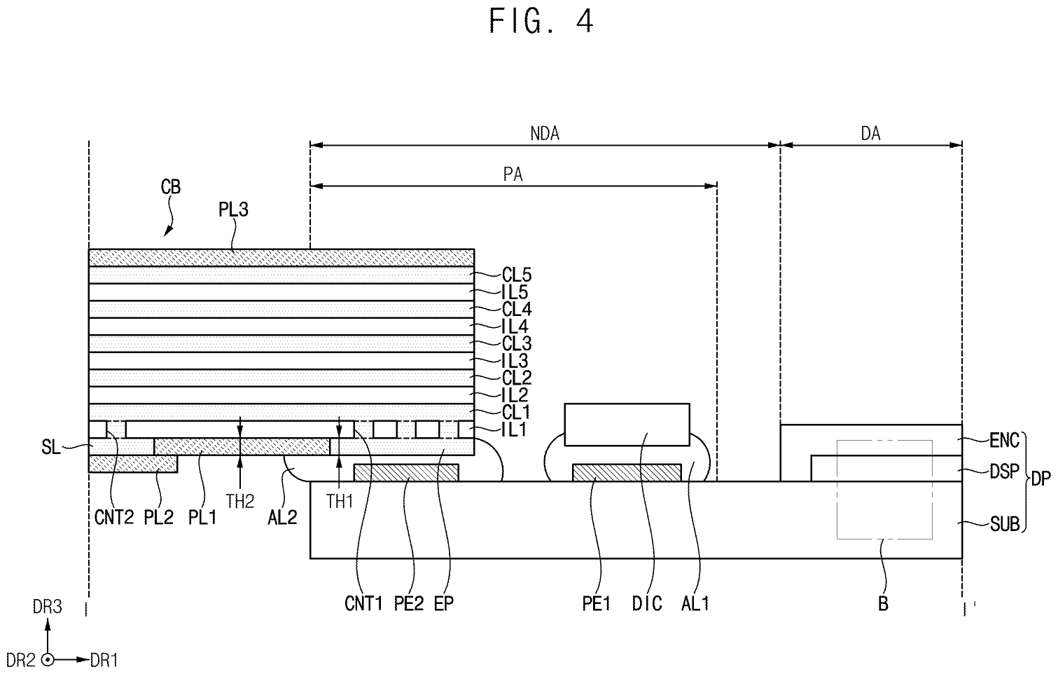

In an embodiment, the circuit board CB may be disposed in the pad area PA on the substrate SUB. Specifically, the circuit board CB may partially overlap the pad area PA. One end of the circuit board CB may be electrically connected to pad electrodes (e.g., second pad electrodes PE2 of FIG. 4) disposed in the pad area PA on the substrate SUB, and the other end of the circuit board CB may be electrically connected an external device. That is, the circuit board CB may be directly connected to the pad electrodes. Accordingly, the dead space of the display device 100 can be reduced. In addition, the manufacturing process of the display device 100 can be simplified. In addition, the manufacturing cost of the display device 100 can be reduced.

In an embodiment, the external device may generate a driving signal and a driving voltage to display an image on the display area DA. The driving signal, the driving voltage, and the like generated from the external device may be provided to the driving integrated circuits DIC and the plurality of pixels PX through the circuit board CB and the pad electrodes. In an embodiment, the circuit board CB may be a printed circuit board (“PCB”). A detailed description of the components of the circuit board CB will be described later.

In this specification, a plane may be defined as the first direction DR1 and the second direction DR2 crossing the first direction DR1.

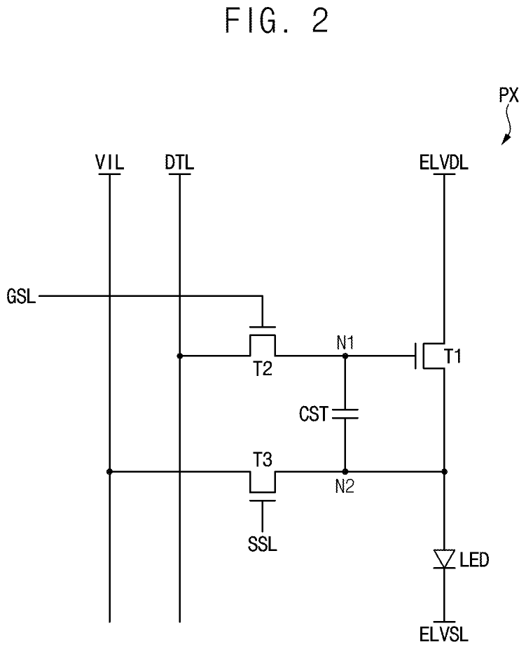

FIG. 2 is a schematic circuit diagram illustrating one pixel of the display device of FIG. 1, according to an embodiment.

Referring to FIG. 2, each of the plurality of pixels PX of the display device 100 according to an embodiment may include first, second, and third transistors T1, T2, and T3, respectively, a storage capacitor CST, and a light emitting element LED.

In an embodiment, the first transistor T1 may include a source electrode, a drain electrode, and a gate electrode. The first transistor T1 may adjust the current flowing from a driving voltage line ELVDL to which the driving voltage is supplied to the light emitting element LED according to the voltage difference between the gate electrode and the source electrode.

In an embodiment, for example, the first transistor T1 may be a driving transistor for driving the light emitting element LED. The gate electrode of the first transistor T1 may be connected to a first node N1. The source electrode of the first transistor T1 may be connected to a first electrode of the light emitting element LED. The drain electrode of the first transistor T1 may be connected to the driving voltage line ELVDL to which the driving voltage is applied.

In an embodiment, the second transistor T2 may include a source electrode, a drain electrode, and a gate electrode. The second transistor T2 may be turned on by a gate signal of a gate signal line GSL to connect a data line DTL to the gate electrode of the first transistor T1. The gate electrode of the second transistor T2 may be connected to the gate signal line GSL. The source electrode of the second transistor T2 may be connected to the first node N1. The drain electrode of the second transistor T2 may be connected to the data line DTL.

In an embodiment, the third transistor T3 may include a source electrode, a drain electrode, and a gate electrode. The third transistor T3 may be turned on by a sensing signal of a sensing signal line SSL to connect an initialization voltage line VIL to one end of the light emitting element LED. The gate electrode of the third transistor T3 may be connected to the sensing signal line SSL. The source electrode of the third transistor T3 may be connected to a second node N2. The drain electrode of the third transistor T3 may be connected to an initialization voltage line VIL to which an initialization voltage is applied.

However, in an embodiment, the source electrode and the drain electrode of each of the first, second, and third transistors T1, T2, and T3, respectively, are not limited thereto, and vice versa. In addition, each of the first, second, and third transistors T1, T2, and T3, respectively, may be formed as a thin film transistor.

In an embodiment, the storage capacitor CST may include a first electrode and a second electrode. The first electrode of the storage capacitor CST may be connected to the first node N1. The second electrode of the storage capacitor CST may be connected to the second node N2. The storage capacitor CST may store a difference voltage between the gate voltage and the source voltage of the first transistor T1.

In an embodiment, the light emitting element LED may emit light according to the current supplied through the first transistor T1. The light emitting element LED may be an organic light emitting diode including a first electrode (e.g., an anode electrode), an organic light emitting layer, and a second electrode (e.g., a cathode electrode). However, embodiments are not limited thereto. The first electrode of the light emitting element LED may be connected to the source electrode of the first transistor T1, and the second electrode of the light emitting element LED may be connected to a common voltage line ELVSL to which a common voltage lower than the driving voltage is applied.

However, in FIG. 2, the embodiment where each pixel PX includes three transistors and one storage capacitor has been described, but embodiments of the invention are not limited thereto.

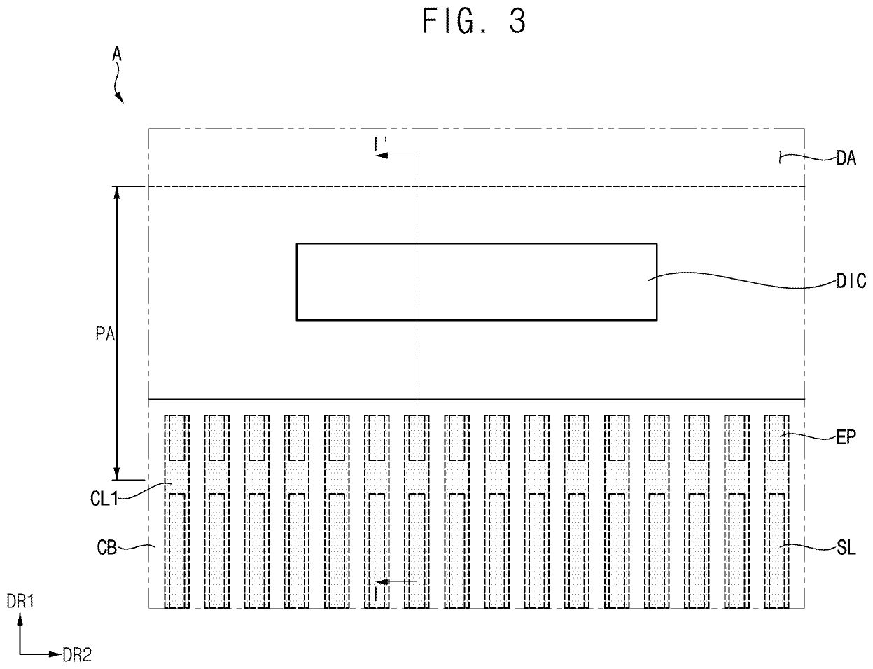

FIG. 3 is an enlarged plan view of area A of FIG. 1, according to an embodiment. FIG. 4 is a cross-sectional view taken along line I-I′ of FIG. 3, according to an embodiment.

FIGS. 1, 3, and 4, the display device 100 according to an embodiment may further include a display portion DSP, an encapsulation layer ENC, a first pad electrode PE1, a second pad electrode PE2, a first adhesive layer AL1, and a second adhesive layer AL2.

In an embodiment, the substrate SUB, the display portion DSP, and the encapsulation layer ENC may constitute the display panel DP. The display portion DSP may be disposed on the substrate SUB, and the encapsulation layer ENC may surround the display portion DSP. A detailed description of components of the display panel DP will be described later.

In an embodiment, the substrate SUB may include a transparent material or an opaque material. The substrate SUB may be made of a transparent resin substrate. In an embodiment, an example of the transparent resin substrate that can be used as the substrate SUB may be a polyimide substrate. In this case, the polyimide substrate may include a first polyimide layer, a barrier film layer, a second polyimide layer, and/or the like. In another embodiment, the substrate SUB may include a quartz substrate, a synthetic quartz substrate, a calcium fluoride substrate, an F-doped quartz substrate, soda-lime glass substrate, a non-alkali glass substrate, and the like. These may be used alone or in combination with each other.

In an embodiment, the first pad electrode PE1 may be disposed in the pad area PA on the substrate SUB. The first pad electrode PE1 may be configured in plurality. In this embodiment, the first pad electrodes PE1 may be spaced apart from each other in the second direction DR2. The first pad electrode PE1 may include an input pad and an output pad. The input pad may receive an input signal, and the output pad may receive an output signal. For example, the first pad electrode PE1 may include a metal, an alloy, a metal nitride, a conductive metal oxide, a transparent conductive material, and/or the like. These may be used alone or in combination with each other.

In an embodiment, the driving integrated circuit DIC may be disposed on the first pad electrode PE1. Specifically, the driving integrated circuit DIC may be coupled to the first pad electrode PE1 through the first adhesive layer AL1. Accordingly, the driving integrated circuit DIC may be electrically connected to the first pad electrode PE1. For example, the first adhesive layer AL1 may include an anisotropic conductive film. The driving integrated circuit DIC may generate the output signal based on the input signal and output the output signal to the output pad.

In an embodiment, the second pad electrode PE2 may be disposed in the pad area PA on the substrate SUB. The second pad electrodes PE2 may be configured in plurality. In this embodiment, the second pad electrodes PE2 may be spaced apart from each other in the second direction DR2. A part of the second pad electrode PE2 may be connected to the first pad electrode PE1 through lines, and the rest of the second pad electrode PE2 may be connected to a plurality of pixels (e.g., the plurality of pixels PX of FIG. 1) through lines. For example, in an embodiment, the second pad electrode PE2 may include a metal, an alloy, a metal nitride, a conductive metal oxide, a transparent conductive material, and/or the like. These may be used alone or in combination with each other.

In an embodiment, the circuit board CB may be disposed on the second pad electrode PE2. The circuit board CB may partially overlap the pad area PA. Specifically, the circuit board CB may be coupled to the second pad electrode PE2 through the second adhesive layer AL2. Accordingly, the circuit board CB may be electrically connected to the second pad electrode PE2. For example, the second adhesive layer AL2 may include an anisotropic conductive film.

In an embodiment, the circuit board CB may include a connection pad EP, a signal line SL, a plurality of insulating layers, at least one conductive layer, and first, second, and third protective layers PL1, PL2, and PL3, respectively,

In an embodiment, the plurality of insulating layers may be disposed on the connection pad EP. In an embodiment, the plurality of insulating layers may include first, second, third, fourth, and fifth insulating layers IL1, IL2, IL3, IL4, and IL5, respectively, sequentially disposed on the connection pad EP. However, embodiments of the invention are not limited thereto, and the number of the plurality of insulating layers may be variously changed.

In an embodiment, for example, each of the first, second, third, fourth, and fifth insulating layers IL1, IL2, IL3, IL4, and IL5, respectively, may include an inorganic insulating material and/or an organic insulating material. These may be used alone or in combination with each other.

In an embodiment, the conductive layer may be disposed on the connection pad EP. Specifically, the conductive layer may be disposed between the plurality of insulating layers. In an embodiment, the conductive layer may include first, second, third, fourth, and fifth conductive layers CL1, CL2, CL3, CL4, and CL5, respectively, sequentially disposed. However, embodiments of the invention are not limited thereto, and the number of conductive layers may be variously changed.

In an embodiment, for example, each of the first, second, third, fourth, and fifth conductive layers CL1, CL2, CL3, CL4, and CL5, respectively, may include copper (Cu). However, embodiments of the invention are not limited thereto, and each of the first, second, third, fourth, and fifth conductive layers CL1, CL2, CL3, CL4, and CL5, respectively, may include various conductive materials.

In an embodiment, the connection pad EP may be disposed under the conductive layer. As described above, the circuit board CB may be coupled to the second pad electrode PE2 through the second adhesive layer AL2. Specifically, the connection pad EP of the circuit board CB may be coupled to the second pad electrode PE2 through the second adhesive layer AL2.

In an embodiment, the signal line SL may be disposed under the conductive layer. In an embodiment, the connection pad EP may be connected to the first conductive layer CL1 through at least one first contact hole CNT1 penetrating the first insulating layer IL1, and the signal line SL may be connected to the second conductive layer CL2 through at least one second contact hole CNT2 penetrating the first insulating layer IL1. Accordingly, the signal line SL may be electrically connected to the connection pad EP through the first conductive layer CL1.

In an embodiment, each of the connection pad EP and the signal line SL may be configured in plurality. In this case, each of the connection pad EP and the signal line SL may be spaced apart from each other in the second direction DR2. In addition, the connection pad EP and the signal line SL may be spaced apart from each other in the first direction DR1.

In an embodiment, for example, each of the connection pad EP and the signal line SL may include copper (Cu). That is, the connection pad EP and the signal line SL may include the same conductive material as the first, second, third, fourth, and fifth conductive layers CL1, CL2, CL3, CL4, and CL5, respectively. However, embodiments of the invention are not limited thereto, and each of the connection pad EP and the signal line SL may include various conductive materials.

In an embodiment, for example, copper (Cu) may be filled in the first and second contact holes CNT1 and CNT2, respectively. However, embodiments of the invention are not limited thereto, and other conductive materials may be filled in the first and second contact holes CNT1 and CNT2, respectively.

In an embodiment, for example, the number of first contact holes CNT1 may be three, and the number of second contact hole CNT2 may be one. However, embodiments of the invention are not limited thereto, and the number of each of the first and second contact holes CNT1 and CNT2, respectively, may be variously changed.

In an embodiment, as the signal line SL is electrically connected to the connection pad EP through the first conductive layer CL1, the first conductive layer CL1 together with the signal line SL and the connection pad EP may serve as lines to which various signals and voltages are applied. In addition, each of the second, third, fourth, and fifth conductive layers CL2, CL3, CL4, and CL5, respectively, may constitute a metal ground layer.

In an embodiment, the first conductive layer CL1 may include a plurality of conductive patterns each extending in the first direction DR1 and spaced apart from each other in the second direction DR2 crossing the first direction DR1. In this embodiment, each of the conductive patterns may overlap the connection pad EP and the signal line SL in a plan view.

In an embodiment, each of the second, third, fourth, and fifth conductive layers CL2, CL3, CL4, and CL5, respectively, may have a plate shape. That is, each of the second, third, fourth, and fifth conductive layers CL2, CL3, CL4, and CL5, respectively, may not include a plurality of conductive patterns.

In an embodiment, the first and second protective layers PL1 and PL2, respectively, may be disposed under the first insulating layer IL1. In addition, the third protective layer PL3 may be disposed on the fifth conductive layer CL5. Specifically, the first protective layer PL1 may be disposed between the connection pad EP and the signal line SL, and the second protective layer PL2 may be disposed under the first protective layer PL1 and the signal line SL. The first, second, and third protective layers PL1, PL2, and PL3, respectively, may protect the metal layer of the circuit board CB. For example, each of the first, second, and third protective layers PL1, PL2, and PL3, respectively, may include a solder resist. Alternatively, the second protective layer PL2 may be integral with the first protective layer PL1.

In an embodiment, when the circuit board CB is coupled to the second pad electrode PE2, the first protective layer PL1 of the circuit board CB may overlap at least a part of the pad area PA. In addition, a lower surface of the first protective layer PL1 may be positioned in the same plane as a lower surface of the connection pad EP. In addition, a thickness TH1 of the connection pad EP in a third direction DR3 may be the same as a thickness TH2 of the first protective layer PL1 in the third direction DR3. That is, a step may not be formed between the first protective layer PL1 and the connection pad EP. Accordingly, compression defect due to lifting between the circuit board CB and the display panel DP can be reduced.

Here, the third direction DR3 may be a direction that is perpendicular to the plane defined by the first and second directions DR1 and DR2.

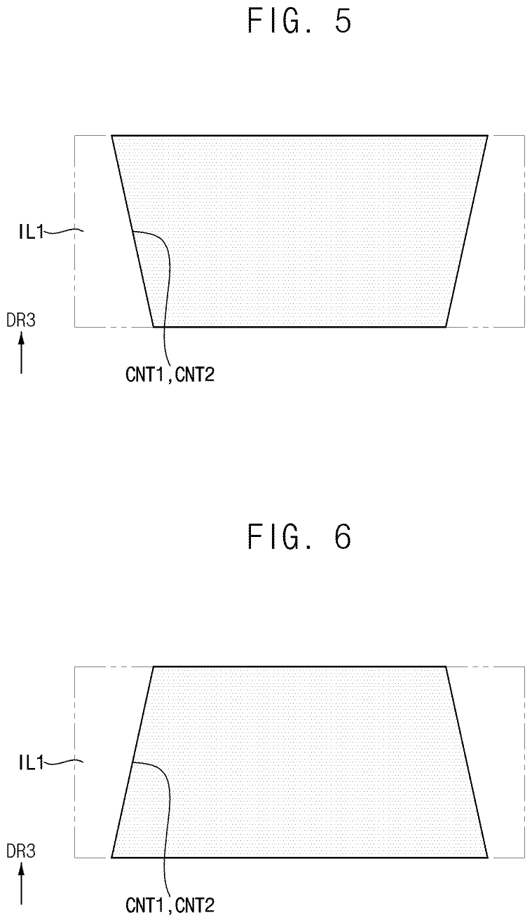

FIGS. 5, 6, 7, and 8 are cross-sectional views illustrating examples of shapes of each of a first contact hole and a second contact hole of FIG. 4, according to embodiments.

In an embodiment and referring to FIGS. 5, 6, 7, and 8, each of the first contact hole CNT1 and the second contact hole CNT2 may have a polygonal cross-sectional shape.

As illustrated in FIG. 5, in an embodiment, each of the first contact hole CNT1 and the second contact hole CNT2 may have an inverted trapezoidal cross-sectional shape.

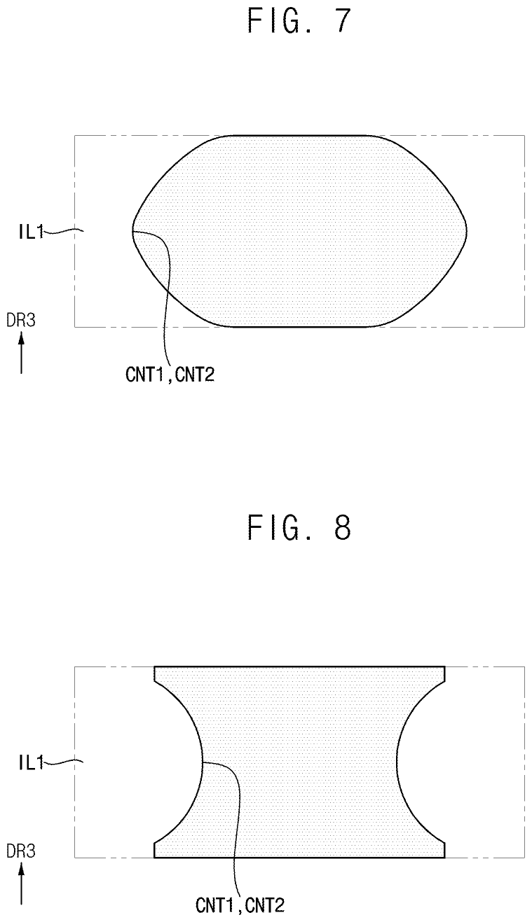

As illustrated in FIG. 6, in an embodiment, each of the first contact hole CNT1 and the second contact hole CNT2 may have a trapezoidal cross-sectional shape.

As illustrated in FIG. 7, in an embodiment, each of the first contact hole CNT1 and the second contact hole CNT2 may have a hexagonal cross-sectional shape.

As illustrated in FIG. 8, in an embodiment, each of the first contact hole CNT1 and the second contact hole CNT2 may have a square cross-sectional shape with side surfaces depressed toward the center.

However, embodiments of the invention are not limited thereto, and each of the first contact hole CNT1 and the second contact hole CNT2 may have various polygonal cross-sectional shapes. In addition, the cross-sectional shape of the first contact hole CNT1 and the cross-sectional shape of the second contact hole CNT2 do not necessarily have to be the same.

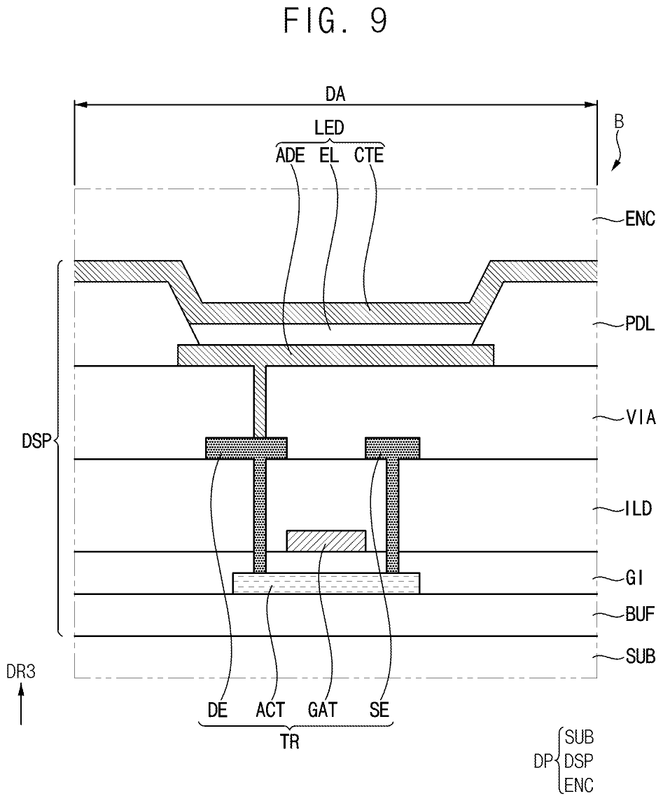

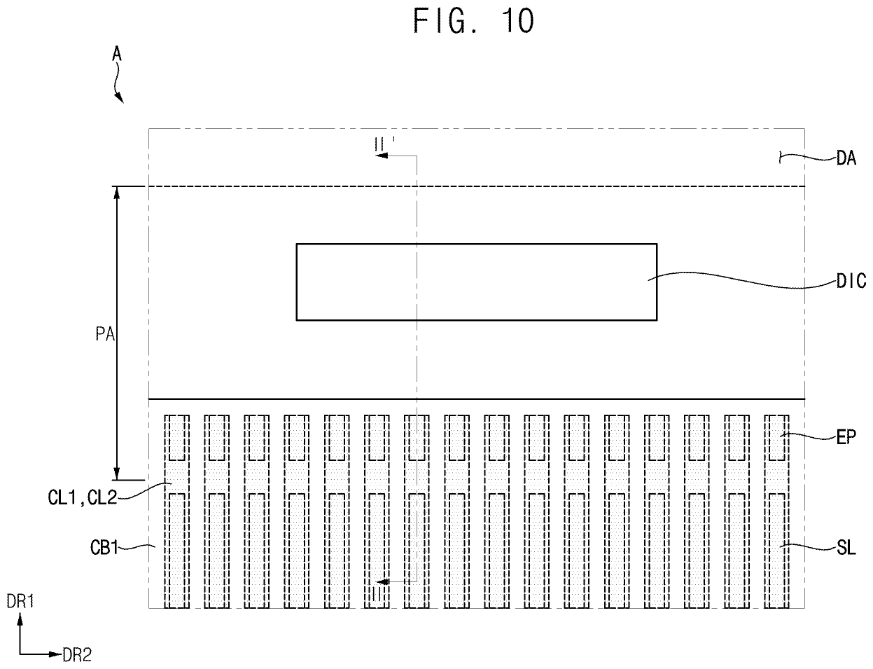

FIG. 9 is an enlarged cross-sectional view of area B of FIG. 4, according to an embodiment.

For example, FIG. 9 is an enlarged cross-sectional view of a part of the display panel DP of FIG. 4.

In an embodiment and referring to FIG. 9, the display panel DP may include the substrate SUB, the display portion DSP, and the encapsulation layer ENC.

Here, In an embodiment, the display portion DSP may include a buffer layer BUF, a transistor TR, a gate insulating layer GI, an interlayer insulating layer ILD, a via insulating layer VIA, a pixel defining layer PDL, and a light emitting element LED. The transistor TR may include an active pattern ACT, a gate electrode GAT, a source electrode SE, and a drain electrode DE, and the light emitting element LED may include an anode electrode ADE, a light emitting layer EL, and a cathode electrode CTE.

In an embodiment, the buffer layer BUF may be disposed on the substrate SUB. The buffer layer BUF may prevent diffusion of metal atoms and/or impurities from the substrate SUB into the transistor TR. In addition, the buffer layer BUF may improve flatness of the surface of the substrate SUB when the surface of the substrate SUB is not uniform. For example, the buffer layer BUF may include an inorganic material such as silicon oxide, silicon nitride, silicon oxynitride, and/or the like. These may be used alone or in combination with each other. In an embodiment, the active pattern ACT may be disposed on the buffer layer BUF.

The active pattern ACT may include a metal oxide semiconductor, an inorganic semiconductor (e.g., amorphous silicon, poly silicon), and/or an organic semiconductor. The active pattern ACT may include a source region, a drain region, and a channel region positioned between the source region and the drain region.

In an embodiment, the metal oxide semiconductor may include a two-component compound (ABₓ), a three-component compound (ABₓC_{y}), a four-component compound (ABₓC_{y}D_{z}), and/or the like containing indium (In), zinc (Zn), gallium (Ga), tin (Sn), titanium (Ti), aluminum (Al), hafnium (Hf), zirconium (Zr), magnesium (Mg), and/or the like. In an embodiment, for example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), and/or the like. These may be used alone or in combination with each other.

In an embodiment, the gate insulating layer GI may be disposed on the buffer layer BUF. The gate insulating layer GI may sufficiently cover the active pattern ACT, and may have a substantially flat upper surface without creating a step around the active pattern ACT. Alternatively, the gate insulating layer GI may cover the active pattern ACT and may be disposed along the profile of the active pattern ACT with a uniform thickness. For example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), and/or the like. These may be used alone or in combination with each other.

In an embodiment, the gate electrode GAT may be disposed on the gate insulating layer GI. The gate electrode GAT may overlap the channel region of the active pattern ACT. The gate electrode GAT may include a metal, an alloy metal nitride, a conductive metal oxide, a transparent conductive material, and/or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and/or the like. Examples of the conductive metal oxide may include indium tin oxide, indium zinc oxide, and/or the like. In addition, examples of the metal nitride may include aluminum nitride (AlNₓ), tungsten nitride (WNₓ), chromium nitride (CrNₓ), and/or the like. Each of these may be used alone or in combination with each other.

In an embodiment, the interlayer insulating layer ILD may be disposed on the gate insulating layer GI. The interlayer insulating layer ILD may sufficiently cover the gate electrodes GAT, and may have a substantially flat upper surface without creating a step around the gate electrode GAT. Alternatively, the interlayer insulating layer ILD may cover the gate electrode GAT and may be disposed along the profile of the gate electrode GAT with a uniform thickness. In an embodiment, for example, the interlayer insulating layer ILD may include an inorganic material such as silicon oxide, silicon nitride, silicon carbide, silicon oxynitride, silicon oxycarbide, and/or the like. These may be used alone or in combination with each other. In an embodiment, the source electrode SE and the drain electrode DE may be disposed on the interlayer insulating layer ILD. The source electrode SE may be connected to the source region of the active pattern ACT through a first contact hole penetrating a first part of the gate insulating layer GI and the interlayer insulating layer ILD. The drain electrode DE may be connected to the drain region of the active pattern ACT through a second contact hole penetrating a second part of the gate insulating layer GI and the interlayer insulating layer ILD. For example, each of the source electrode SE and the drain electrode DE may include a metal, an alloy, a metal nitride, a conductive metal oxide, a transparent conductive material, and/or the like. These may be used alone or in combination with each other.

Accordingly, in an embodiment, the transistor TR including the active pattern ACT, the gate electrode GAT, the source electrode SE, and the drain electrode DE may be disposed in the display area DA on the substrate SUB.

In an embodiment, the via insulating layer VIA may be disposed on the interlayer insulation layer ILD. The via insulating layer VIA may sufficiently cover the source electrode SE and the drain electrode DE. The via insulating layer VIA may include an inorganic material and/or an organic material. For example, the via insulating layer VIA may include phenolic resin, polyacrylates resin, polyimides rein, polyamides resin, siloxane resin, epoxy resin, and/or the like. These may be used alone or in combination with each other.

In an embodiment, the anode electrode ADE may be disposed on the via insulating layer VIA. The anode electrode ADE may be connected to the drain electrode DE of the transistor TR through a contact hole penetrating the via insulating layer VIA. In an embodiment, for example, the anode electrode ADE may include a metal, an alloy, a metal nitride, a conductive metal oxide, a transparent conductive material, and/or the like. These may be used alone or in combination with each other. In an embodiment, the anode electrode ADE may have a stacked structure including ITO/Ag/ITO.

In an embodiment, the pixel defining layer PDL may be disposed on the via insulating layer VIA. The pixel defining layer PDL may cover an edge of the anode electrode ADE. The pixel defining layer PDL may include an organic material and/or an organic material. For example, the pixel defining layer PDL may include an organic material such as an epoxy resin, a siloxane resin, and/or the like. These may be used alone or in combination with each other. In another embodiment, the pixel defining layer PDL may include an organic material and/or an inorganic material containing a light-blocking material such as a black pigment, black dye, and/or the like.

In an embodiment, the light emitting layer EL may be disposed on the anode electrode ADE. The light emitting layer EL may include an organic material that emits light of a predetermined color. For example, the light emitting layer EL may include an organic material that emits red light, green light, or blue light.

In an embodiment, the cathode electrode CTE may be disposed on the light emitting layer EL and the pixel defining layer PDL. For example, the cathode electrode CTE may include a metal, an alloy, a metal nitride, a conductive metal oxide, a transparent conductive material, and/or the like. These may be used alone or in combination with each other.

Accordingly, in an embodiment, the light emitting device LED including the anode electrode ADE, the light emitting layer EL, and the cathode electrode CTE may be disposed in the display area DA on the substrate SUB.

In an embodiment, the encapsulation layer ENC may be disposed on the cathode electrode CTE. The encapsulation layer ENC may prevent impurities, moisture, air, and/or the like from permeating the light emitting device LED from the outside. The encapsulation layer ENC may include at least one inorganic layer and at least one organic layer. For example, the inorganic layer may include silicon oxide, silicon nitride, silicon oxynitride, and/or the like. These may be used alone or in combination with each other. The organic layer may include a polymer cured material such as polyacrylate, and/or the like.

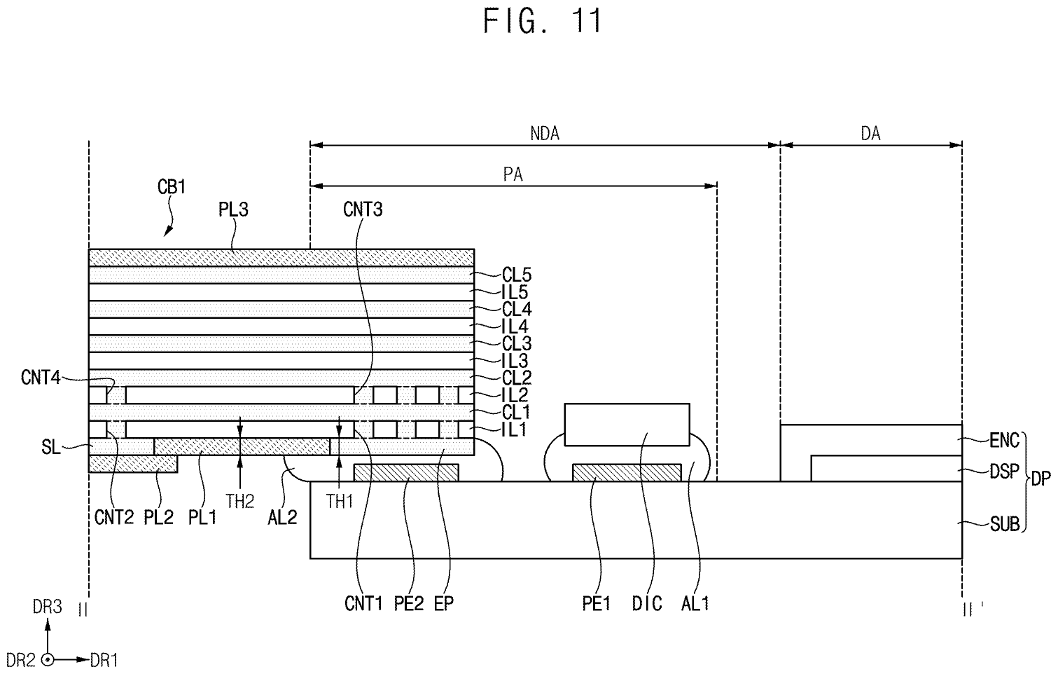

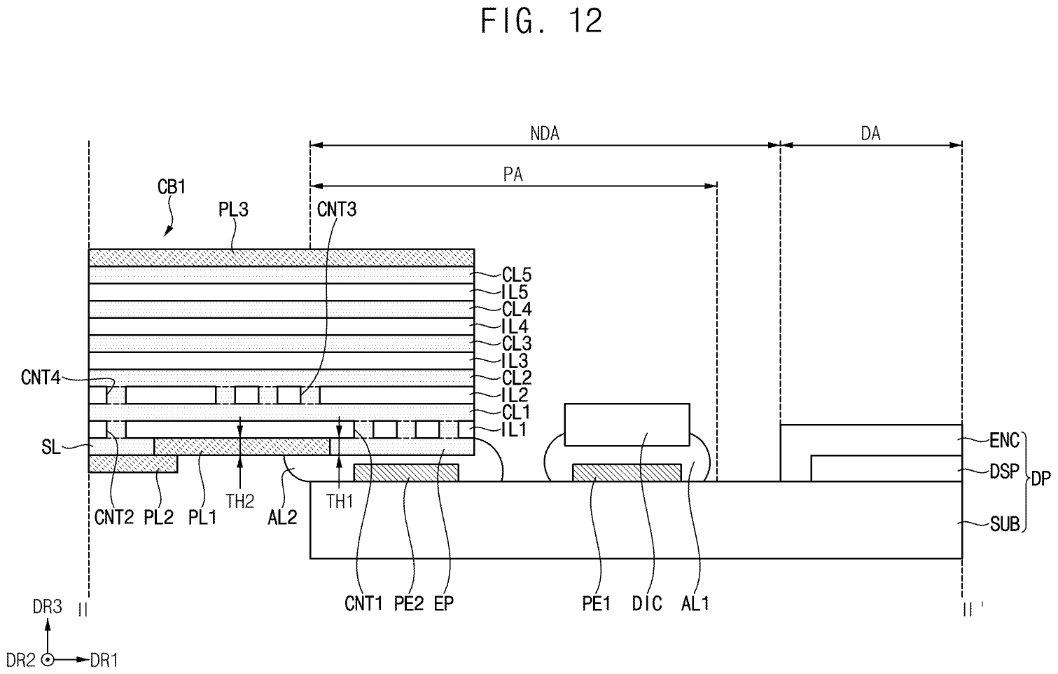

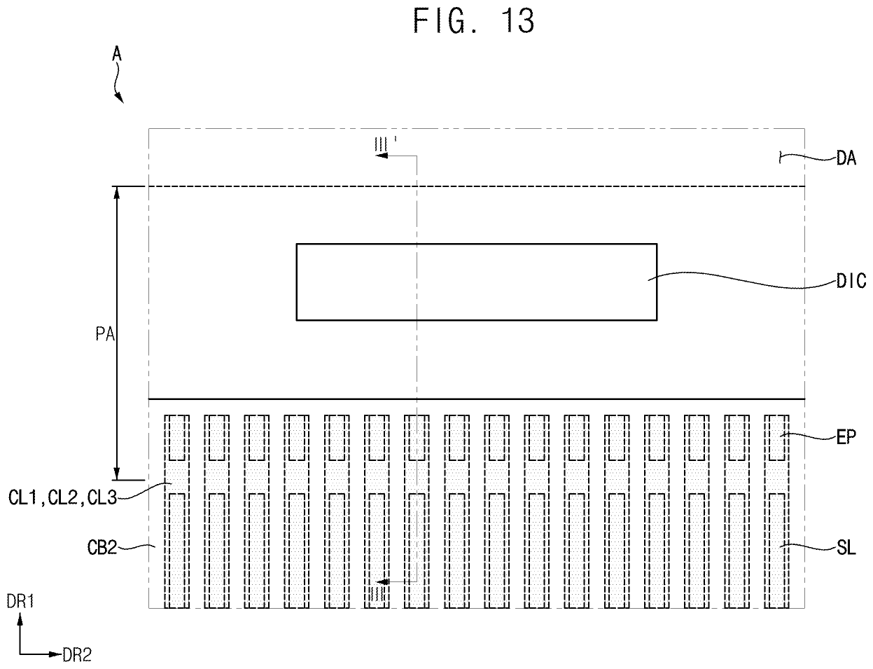

FIG. 10 is an enlarged plan view of another example of area A of FIG. 1, according to an embodiment. FIG. 11 is a cross-sectional view illustrating an example of a cross section taken along line II-II′ of FIG. 10, according to an embodiment. FIG. 12 is a cross-sectional view illustrating another example of a cross section taken along line II-II′ of FIG. 10, according to an embodiment.

Hereinafter, descriptions overlapping those of the display device 100 described with reference to FIGS. 3 and 4 will be omitted or simplified.

Referring to FIGS. 1, 10, 11, and 12, the display device according to an embodiment may include the substrate SUB, the display portion DSP, the encapsulation layer ENC, the driving integrated circuit DIC, a circuit board CB1, the first pad electrode PE1, the second pad electrode PE2, the first adhesive layer AL1, and the second adhesive layer AL2.

In an embodiment, the circuit board CB1 may include a connection pad EP, a signal line SL, a plurality of insulating layers, at least one conductive layer, and first, second, and third protective layers PL1, PL2, and PL3, respectively.

In an embodiment, the plurality of insulating layers may include first, second, third, fourth, and fifth insulating layers IL1, IL2, IL3, IL4, and IL5, respectively, sequentially disposed on the connection pad EP.

In an embodiment, the conductive layer may include first, second, third, fourth, and fifth conductive layers CL1, CL2, CL3, CL4, and CL5, respectively, sequentially disposed. For example, each of the first, second, third, fourth, and fifth conductive layers CL1, CL2, CL3, CL4, and CL5, respectively, may include copper (Cu).

In an embodiment, the connection pad EP may be disposed under the conductive layer. The connection pad EP of the circuit board CB1 may be coupled to the second pad electrode PE2 through the second adhesive layer AL2.

In an embodiment, the signal line SL may be disposed under the conductive layer. In an embodiment, the connection pad EP may be connected to the first conductive layer CL1 through at least one first contact hole CNT1 penetrating the first insulating layer IL1, and the signal line may be connected to the first conductive layer CL1 through at least one second contact hole CNT2 penetrating the first insulating layer IL1. In addition, the first conductive layer CL1 may be connected to the second conductive layer CL2 through at least one third contact hole CNT3 and at least one fourth contact hole CNT4 penetrating the second insulating layer IL2. Accordingly, the signal line SL may be electrically connected to the connection pad EP through the first conductive layer CL1 and the second conductive layer CL2.

In an embodiment, as the signal line SL is electrically connected to the connection pad EP through the first conductive layer CL1 and the second conductive layer CL2, the first conductive layer CL1 and the second conductive layer CL2 together with the signal line SL and the connection pad EP may serve as lines to which various signals and voltages are applied. In addition, each of the third, fourth, and fifth conductive layers CL3, CL4, and CL5, respectively, may constitute a metal ground layer.

In an embodiment, each of the first and second conductive layers CL1 and CL2, respectively, may include a plurality of conductive patterns each extending in the first direction DR1 and spaced apart from each other in the second direction DR2 crossing the first direction DR1. In an embodiment, each of the conductive patterns may overlap the connection pad EP and the signal line SL in the plan view.

In an embodiment, each of the third, fourth, and fifth conductive layers CL3, CL4, and CL5, respectively, may have a plate shape. That is, each of the third, fourth, and fifth conductive layers CL3, CL4, and CL5, respectively, may not include a plurality of conductive patterns.

In an embodiment, each of the connection pad EP and the signal line SL may be configured in plurality. In an embodiment, each of the connection pad EP and the signal line SL may be arranged to be spaced apart from each other in the second direction DR2. In addition, the connection pad EP and the signal line SL may be spaced apart from each other in the first direction DR1.

In an embodiment, for example, each of the connection pad EP and the signal line SL may include copper (Cu). That is, the connection pad EP and the signal line SL may include the same conductive material as the first, second, third, fourth, and fifth conductive layers CL1, CL2, CL3, CL4, and CL5, respectively.

In an embodiment, for example, copper (Cu) may be filled in the first, second, third, and fourth contact holes CNT1, CNT2, CNT3, and CNT4, respectively. However, embodiments of the invention are not limited thereto, and other conductive materials may be filled in the first, second, third, and fourth contact holes CNT1, CNT2, CNT3, and CNT4, respectively.

In an embodiment, each of the first, second, third, and fourth contact holes CNT1, CNT2, CNT3, and CNT4, respectively, may have a polygonal cross-sectional shape. For example, each of the first, second, third, and fourth contact holes CNT1, CNT2, CNT3, and CNT4, respectively, may have an inverted trapezoidal cross-sectional shape, a trapezoidal cross-sectional shape, a hexagonal cross-sectional shape, or a square cross-sectional shape with side surfaces depressed toward the center

In an embodiment, for example, the number of each of the first and third contact holes CNT1 and CNT3, respectively, may be three, and the number of each of the second and fourth contact holes CNT2 and CNT4, respectively, may be one. However, embodiments of the invention are not limited thereto, and the number of each of the first, second, third, and fourth contact holes CNT1, CNT2, CNT3, and CNT4, respectively, may be variously changed.

In an embodiment, positions of the third and fourth contact holes CNT3 and CNT4, respectively, may be variously changed. For example, as illustrated n in FIG. 11, the third contact hole CNT3 may overlap the first contact hole CNT1 in the plan view, and the fourth contact hole CNT4 may overlap the second contact hole CNT2 in the plan view. Alternatively, as illustrated in FIG. 12, the third contact hole CNT3 may not overlap the first contact hole CNT1 in the plan view.

In an embodiment, the first and second protective layers PL1 and PL2, respectively, may be disposed under the first insulating layer IL1. In addition, the third protective layer PL3 may be disposed on the fifth conductive layer CL5. Specifically, the first protective layer PL1 may be disposed between the connection pad EP and the signal line SL, and the second protective layer PL2 may be disposed under the first protective layer PL1 and the signal line SL. In an embodiment, for example, each of the first, second, and third protective layers PL1, PL2, and PL3, respectively, may include a solder resist. Alternatively, the second protective layer PL2 may be integral with the first protective layer PL1.

In an embodiment, when the circuit board CB1 is coupled to the second pad electrode PE2, the first protective layer PL1 of the circuit board CB1 may overlap at least a part of the pad area PA. In addition, a lower surface of the first protective layer PL1 may be positioned in the same plane as a lower surface of the connection pad EP. In addition, the thickness TH1 of the connection pad EP in the third direction DR3 may be the same as the thickness TH2 of the first protective layer PL1 in the third direction DR3. That is, a step may not be formed between the first protective layer PL1 and the connection pad EP. Accordingly, compression defect due to lifting between the circuit board CB1 and the display panel DP can be reduced.

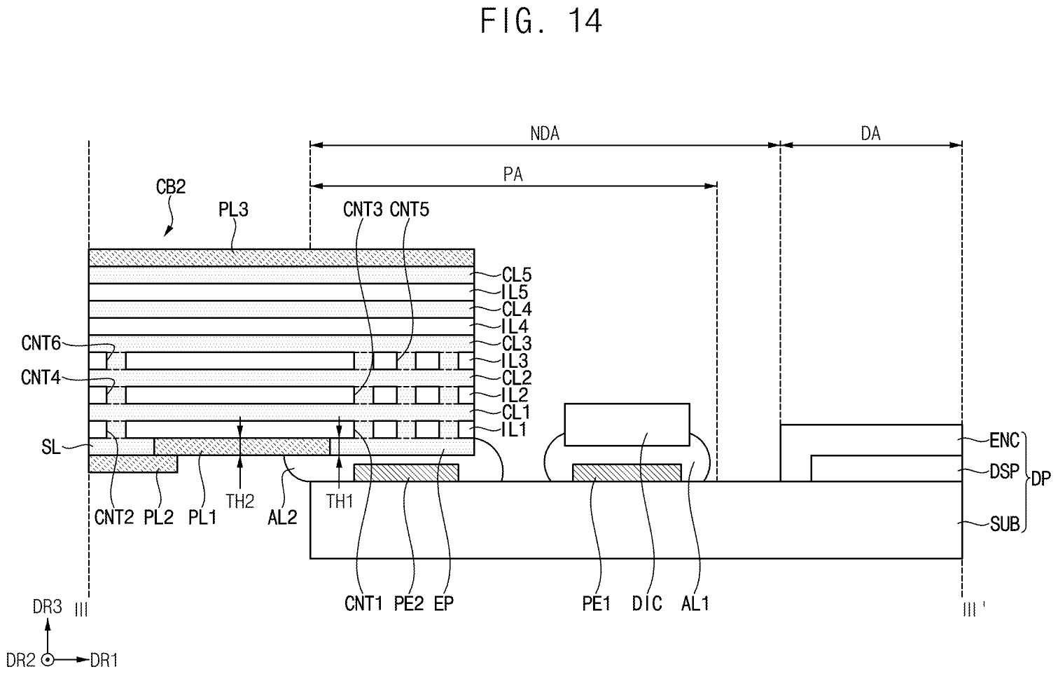

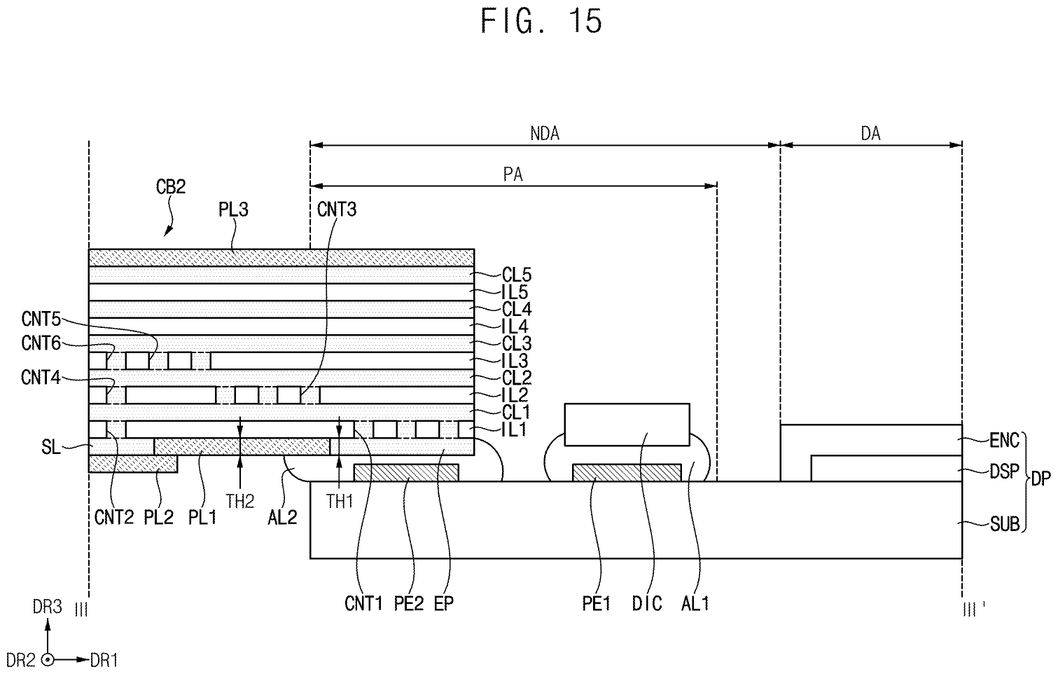

FIG. 13 is an enlarged plan view of another example of area A of FIG. 1, according to an embodiment. FIG. 14 is a cross-sectional view illustrating an example of a cross section taken along line III-III′ of FIG. 13, according to an embodiment. FIG. 15 is a cross-sectional view illustrating another example of a cross section taken along line III-III′ of FIG. 13, according to an embodiment.

Hereinafter, descriptions overlapping those of the display device 100 described with reference to FIGS. 3 and 4 will be omitted or simplified.

Referring to FIGS. 1, 13, 14, and 15, the display device according to an embodiment may include the substrate SUB, the display portion DSP, the encapsulation layer ENC, the driving integrated circuit DIC, a circuit board CB2, the first pad electrode PE1, the second pad electrode PE2, the first adhesive layer AL1, and the second adhesive layer AL2.

In an embodiment, the circuit board CB2 may include a connection pad EP, a signal line SL, a plurality of insulating layers, at least one conductive layer, and first, second, and third protective layers PL1, PL2, and PL3, respectively.

In an embodiment, the plurality of insulating layers may include first, second, third, fourth, and fifth insulating layers IL1, IL2, IL3, IL4, and IL5, respectively, sequentially disposed on the connection pad EP.

In an embodiment, the conductive layer may include first, second, third, fourth, and fifth conductive layers CL1, CL2, CL3, CL4, and CL5, respectively, sequentially disposed. For example, each of the first, second, third, fourth, and fifth conductive layers CL1, CL2, CL3, CL4, and CL5, respectively, may include copper (Cu).

In an embodiment, the connection pad EP may be disposed under the conductive layer. The connection pad EP of the circuit board CB2 may be coupled to the second pad electrode PE2 through the second adhesive layer AL2.

In an embodiment, the signal line SL may be disposed under the conductive layer. In an embodiment, the connection pad EP may be connected to the first conductive layer CL1 through at least one first contact hole CNT1 penetrating the first insulating layer IL1, and the signal line may be connected to the first conductive layer CL1 through at least one second contact hole CNT2 penetrating the first insulating layer IL1. In addition, the first conductive layer CL1 may be connected to the second conductive layer CL2 through at least one third contact hole CNT3 and at least one fourth contact hole CNT4 penetrating the second insulating layer IL2. In addition, the second conductive layer CL2 may be connected to the third conductive layer CL3 through at least one fifth contact hole CNT5 and at least one sixth contact hole CNT6 penetrating the third insulating layer IL3. Accordingly, the signal line SL may be electrically connected to the connection pad EP through the first conductive layer CL1, the second conductive layer CL2, and the third conductive layer CL3.

In an embodiment, as the signal line SL is electrically connected to the connection pad EP through the first conductive layer CL1, the second conductive layer CL2, and the third conductive layer CL3, the first conductive layer CL1, the second conductive layer CL2, and the third conductive layer CL3 together with the signal line SL and the connection pad EP may serve as lines to which various signals and voltages are applied. In addition, each of the fourth and fifth conductive layers CL4 and CL5, respectively, may constitute a metal ground layer.

In an embodiment, each of the first, second, and third conductive layers CL1, CL2, and CL3, respectively, may include a plurality of conductive patterns each extending in the first direction DR1 and spaced apart from each other in the second direction DR2 crossing the first direction DR1. In this case, each of the conductive patterns may overlap the connection pad EP and the signal line SL in the plan view.

In an embodiment, each of the fourth, and fifth conductive layers CL4, and CL5, respectively, may have a plate shape. That is, each of the fourth, and fifth conductive layers CL4, and CL5, respectively, may not include a plurality of conductive patterns.

In an embodiment, each of the fourth, and fifth conductive layers CL4, and CL5, respectively, may have a plate shape. That is, each of the fourth, and fifth conductive layers CL4, and CL5, respectively, may not include a plurality of conductive patterns.

In an embodiment, each of the connection pad EP and the signal line SL may be configured in plurality. In an embodiment, each of the connection pad EP and the signal line SL may be arranged to be spaced apart from each other in the second direction DR2. In addition, the connection pad EP and the signal line SL may be spaced apart from each other in the first direction DR1.

In an embodiment, for example, each of the connection pad EP and the signal line SL may include copper (Cu). That is, the connection pad EP and the signal line SL may include the same conductive material as the first, second, third, fourth, and fifth conductive layers CL1, CL2, CL3, CL4, and CL5, respectively.

In an embodiment, for example, copper (Cu) may be filled in the first, second, third, fourth, fifth, and sixth contact holes CNT1, CNT2, CNT3, CNT4, CNT5, and CNT6, respectively. However, embodiments of the invention are not limited thereto, and other conductive materials may be filled in the first, second, third, fourth, fifth, and sixth contact holes CNT1, CNT2, CNT3, CNT4, CNT5, and CNT6, respectively.

In an embodiment, each of the first, second, third, fourth, fifth, and sixth contact holes CNT1, CNT2, CNT3, CNT4, CNT5, and CNT6, respectively, may have a polygonal cross-sectional shape. For example, each of the first, second, third, fourth, fifth, and sixth contact holes CNT1, CNT2, CNT3, CNT4, CNT5, and CNT6, respectively, may have an inverted trapezoidal cross-sectional shape, a trapezoidal cross-sectional shape, a hexagonal cross-sectional shape, or a square cross-sectional shape with side surfaces depressed toward the center.

In an embodiment, for example, the number of each of the first, third, and fifth contact holes CNT1, CNT3, and CNT5, respectively, may be three, and the number of each of the second, fourth, and sixth contact holes CNT2, CNT4, and CNT6, respectively, may be one. However, embodiments of the invention are not limited thereto, and the number of each of the first, second, third, fourth, fifth, and sixth contact holes CNT1, CNT2, CNT3, CNT4, CNT5, and CNT6, respectively, may be variously changed.

In an embodiment, positions of the third, fourth, fifth, and sixth contact holes CNT3, CNT4, CNT5, and CNT6, respectively, may be variously changed. For example, as illustrated in FIG. 14, the third and fifth contact holes CNT3 and CNT5, respectively, may overlap the first contact hole CNT1 in the plan view, and the fourth and sixth contact holes CNT4 and CNT6, respectively, may overlap the second contact hole CNT2 in the plan view. Alternatively, as illustrated in FIG. 15, the third and fifth contact hole CNT3 and CNT5, respectively, may not overlap the first contact hole CNT1 in the plan view.

In an embodiment, the first and second protective layers PL1 and PL2 may be disposed under the first insulating layer IL1. In addition, the third protective layer PL3 may be disposed on the fifth conductive layer CL5. Specifically, the first protective layer PL1 may be disposed between the connection pad EP and the signal line SL, and the second protective layer PL2 may be disposed under the first protective layer PL1. For example, each of the first, second, and third protective layers PL1, PL2, and PL3, respectively, may include a solder resist. Alternatively, the second protective layer PL2 may be integral with the first protective layer PL1.

In an embodiment, when the circuit board CB2 is coupled to the second pad electrode PE2, the first protective layer PL1 of the circuit board CB2 may overlap at least a part of the pad area PA. In addition, a lower surface of the first protective layer PL1 may be positioned in the same plane as a lower surface of the connection pad EP. In addition, the thickness TH1 of the connection pad EP in the third direction DR3 may be the same as the thickness TH2 of the first protective layer PL1 in the third direction DR3. That is, a step may not be formed between the first protective layer PL1 and the connection pad EP. Accordingly, compression defect due to lifting between the circuit board CB2 and the display panel DP can be reduced.

However, although embodiments referring to FIGS. 3, 4, 10, 11, 12, 13, 14, and 15, electrical connection of the connection pad EP and the signal lines SL through one, two, or three conductive layers has been described as an example, but embodiments of the invention are not limited thereto. In an embodiment, for example, the connection pad EP and the signal line SL may be electrically connected through four or more conductive layers.

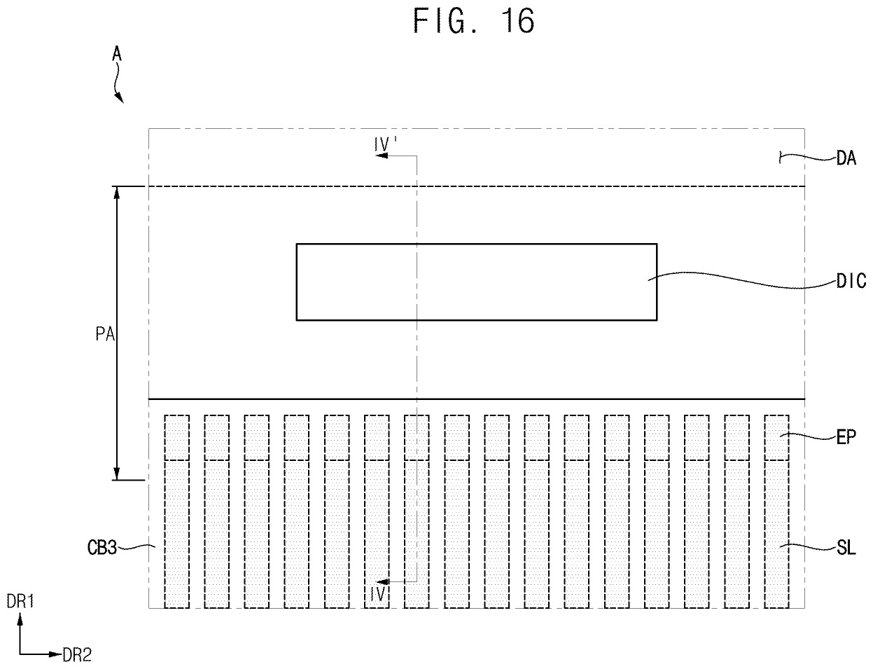

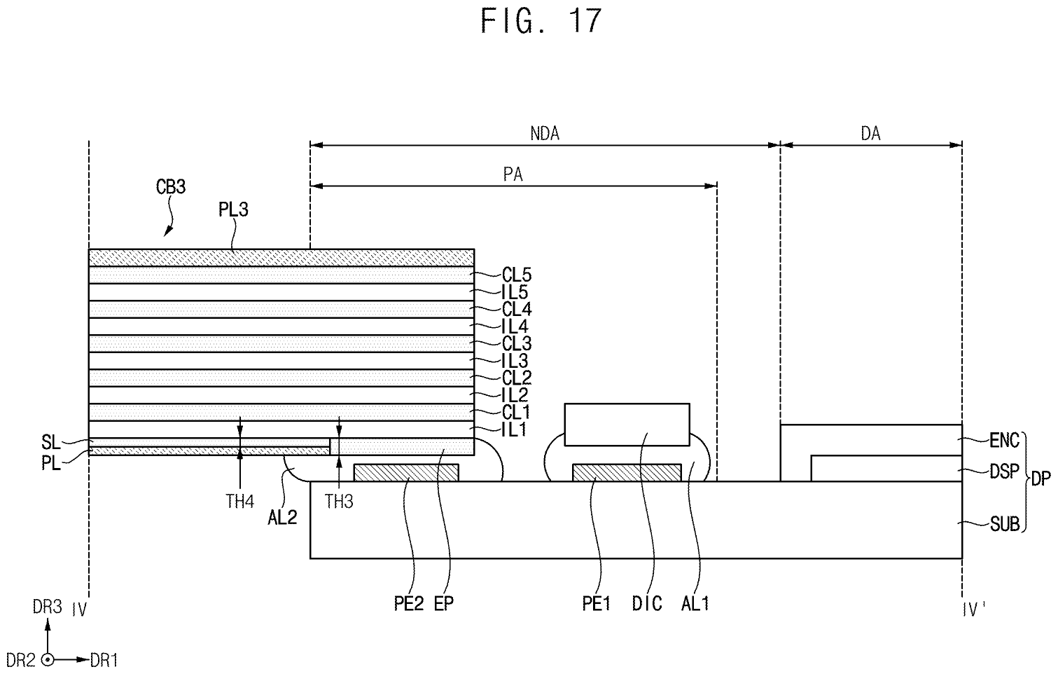

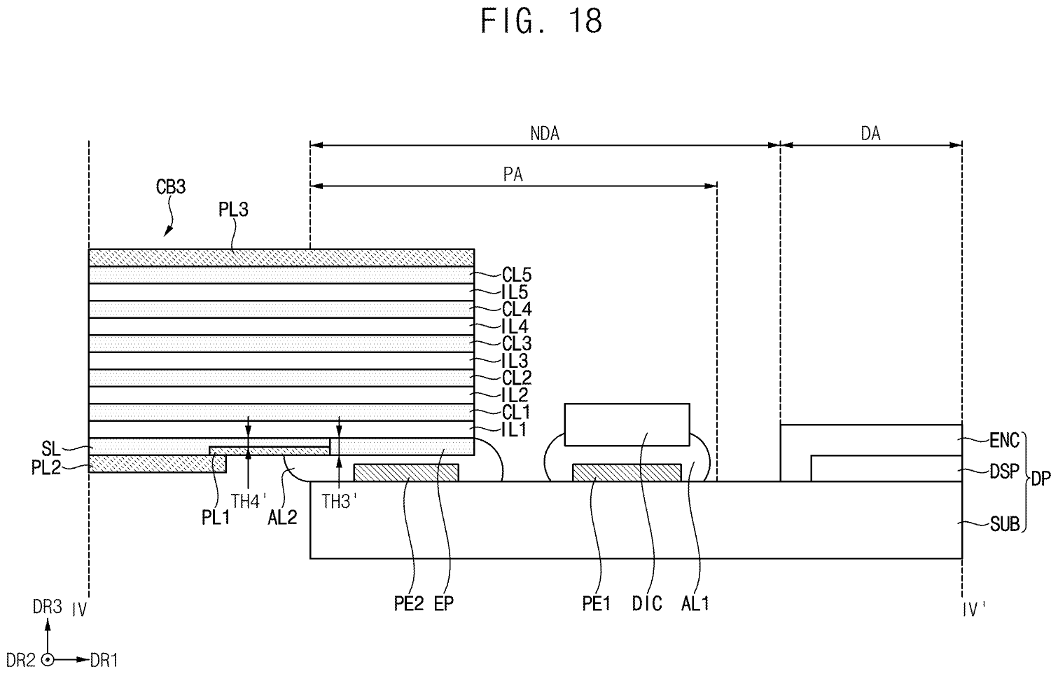

FIG. 16 is an enlarged plan view of another example of area A of FIG. 1, according to an embodiment. FIG. 17 is a cross-sectional view illustrating an example of a cross section taken along line IV-IV′ of FIG. 16, according to an embodiment. FIG. 18 is a cross-sectional view illustrating another example of a cross section taken along line IV-IV′ of FIG. 16, according to an embodiment.

Hereinafter, descriptions overlapping those of the display device 100 described with reference to FIGS. 3 and 4 will be omitted or simplified.

Referring to FIGS. 1, 16, 17, and 18, the display device according to an embodiment may include the substrate SUB, the display portion DSP, the encapsulation layer ENC, the driving integrated circuit DIC, a circuit board CB3, the first pad electrode PE1, the second pad electrode PE2, the first adhesive layer AL1, and the second adhesive layer AL2.

In an embodiment, a plurality of insulating layers may be disposed on a connection pad EP. In an embodiment, the plurality of insulating layers may include first, second, third, fourth, and fifth insulating layers IL1, IL2, IL3, IL4, and IL5, respectively, sequentially disposed on the connection pad EP.

In an embodiment, the conductive layer may be disposed on the connection pad EP. In an embodiment, the conductive layer may include first, second, third, fourth, and fifth conductive layers CL1, CL2, CL3, CL4, and CL5, respectively, sequentially disposed. For example, each of the first, second, third, fourth, and fifth conductive layers CL1, CL2, CL3, CL4, and CL5, respectively, may include copper (Cu).

In an embodiment, the connection pad EP may be disposed under the conductive layer. The connection pad EP of the circuit board CB3 may be coupled to the second pad electrode PE2 through the second adhesive layer AL2.

In an embodiment, the signal line SL may be disposed under the conductive layer. The signal line SL may not overlap the connection pad EP in the plan view. In an embodiment, the connection pad EP may be integral with the signal line SL. Accordingly, the signal line SL may be electrically connected to the connection pad EP.

In an embodiment, the signal line SL and the connection pad EP may serve as lines to which various signals and voltages are applied. In addition, each of the first, second, third, fourth, and fifth conductive layers CL1, CL2, CL3, CL4, and CL5, respectively, may constitute a metal ground layer.

In an embodiment, the connection pad EP and the signal line SL may be configured in plurality. In an embodiment, the connection pad EP and the signal line SL may be arranged to be spaced apart from each other in the second direction DR2.

In an embodiment, for example, each of the connection pad EP and the signal line SL may include copper (Cu). That is, the connection pad EP and the signal line SL may include the same conductive material as the first, second, third, fourth, and fifth conductive layers CL1, CL2, CL3, CL4, and CL5, respectively.

In an embodiment, each of the first, second, third, fourth, and fifth conductive layers CL1, CL2, CL3, CL4, and CL5, respectively, may have a plate shape. That is, each of the first, second, third, fourth, and fifth conductive layers CL1, CL2, CL3, CL4, and CL5, respectively, may not include a plurality of conductive patterns.

As illustrated in FIG. 17, in an embodiment, a protective layer PL may be disposed under the signal line SL. For example, the protective layer PL may include a solder resist.

In an embodiment, when the circuit board CB3 is coupled to the second pad electrode PE2, the protective layer PL of the circuit board CB3 may overlap at least a part of the pad area PA. In addition, a lower surface of the protective layer PL may be positioned in the same plane as a lower surface of the connection pad EP. In addition, the thickness TH4 of the signal line SL in the third direction DR3 may be smaller than the thickness TH3 of the connection pad EP in the third direction DR3. That is, a step may not be formed between the protective layer PL and the connection pad EP. Accordingly, compression defect due to lifting between the circuit board CB3 and the display panel DP can be reduced.

As illustrated in FIG. 18, in another embodiment, first and second protective layers PL1 and PL2, respectively, may be disposed under the signal line SL. Specifically, the second protective layer PL2 may be disposed under the first protective layer PL1. For example, each of the first and second protective layers PL1 and PL2 may include a solder resist.

In another embodiment, when the circuit board CB3 is coupled to the second pad electrode PE2, the first protective layer PL1 of the circuit board CB3 may overlap at least a part of the pad area PA. In addition, a lower surface of the first protective layer PL1 may be positioned in the same plane as a lower surface of the connection pad EP. In addition, a thickness TH4′ of a part of the signal line SL overlapping the first protective layer PL1 in the third direction DR3 may be smaller than a thickness TH3′ of the connection pad EP in the third direction DR3. That is, a step may not be formed between the first protective layer PL1 and the connection pad EP. Accordingly, compression defect due to lifting between the circuit board CB3 and the display panel DP may be reduced.

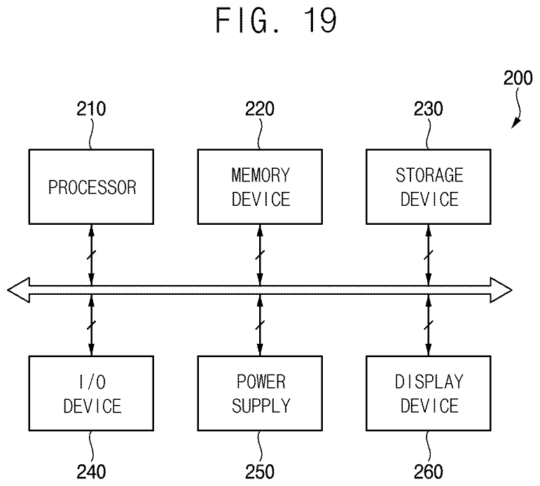

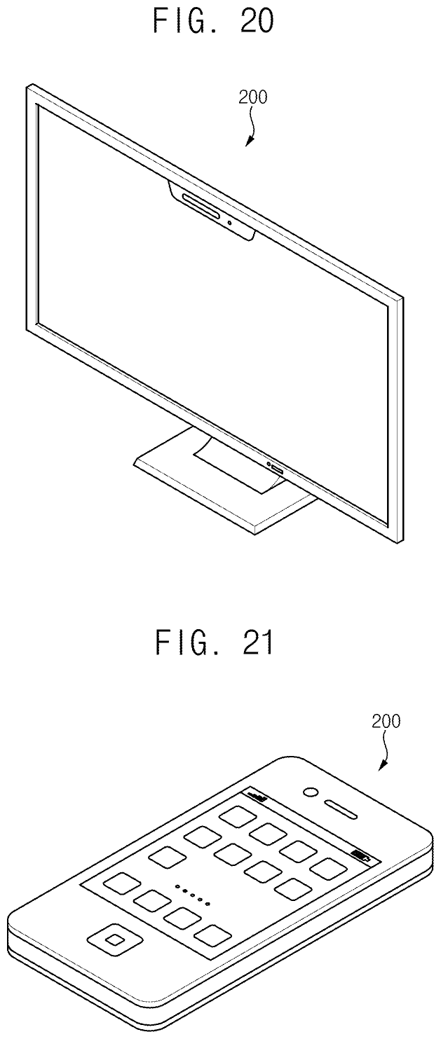

FIG. 19 is a block diagram illustrating an electronic device including the display device of FIG. 1, according to an embodiment. FIG. 20 is a perspective view illustrating an example in which the electronic device of FIG. 19 is implemented as a television, according to an embodiment. FIG. 21 is a perspective view illustrating an example in which the electronic device of FIG. 19 is implemented as a smartphone, according to an embodiment.

Referring to FIGS. 19, 20, and 21, in an embodiment, an electronic device 200 may include a processor 210, a memory device 220, a storage device 230, an input/output device 240, a power supply 250, and a display device 260. In an embodiment, the display device 260 may correspond to the display device 10 described with reference to FIGS. 1 to 18. The electronic device 200 may further include several ports capable of communicating with a video card, a sound card, a memory card, a USB device, and/or the like.

In an embodiment, as illustrated in FIG. 20, the electronic device 200 may be implemented as a television. In another embodiment, as illustrated in FIG. 21, the electronic device 900 may be implemented as a smart phone. However, the electronic device 200 is not limited thereto, and for example, the electronic device 200 may be implemented as a mobile phone, a video phone, a smart pad, a smart watch, a tablet PC, a vehicle navigation device, a computer monitor, a laptop computer, a head mounted display (HMD), and/or the like.

In an embodiment, the processor 210 may perform certain calculations or tasks. In an embodiment, the processor 210 may be a microprocessor, a central processing unit (CPU), an application processor (AP), and/or the like. The processor 210 may be connected to other components through an address bus, a control bus, a data bus, and/or the like. The processor 210 may also be connected to an expansion bus, such as a peripheral component interconnect (PCI) bus.

In an embodiment, the memory device 220 may store data necessary for the operation of the electronic device 200. For example, the memory device 220 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and/or the like.

In an embodiment, the storage device 230 may include a solid-state drive (SSD), a hard disk drive (HDD), a CD-ROM, and/or the like.

In an embodiment, the input/output device 240 may include input means such as a keyboard, keypad, touch pad, touch screen, mouse, and/or the like and output means such as a speaker, a printer, and/or the like.

In an embodiment, the power supply 250 may supply power necessary for the operation of the electronic device 200. The display device 260 may be connected to other components through buses and/or other communication links. In an embodiment, the display device 260 may be included in the input/output device 240.

The invention can be applied to various display devices. In an embodiment, for example, the invention is applicable to various display devices such as display devices for vehicles, ships and aircraft, portable communication devices, display devices for exhibition or information transmission, medical display devices, and/or the like.

The foregoing is illustrative of embodiments and is not to be construed as limiting thereof. Although a few embodiments have been described, those skilled in the art will readily appreciate that many modifications are possible in the embodiments without materially departing from the teachings and advantages of the invention. Accordingly, all such modifications are intended to be included within the scope of the invention. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims. Moreover, the embodiments or parts of the embodiments may be combined in whole or in part without departing from the scope of the invention.

What is claimed is:

1. A circuit board comprising:
a plurality of insulating layers;
at least one conductive layer disposed between the plurality of insulating layers;
a connection pad disposed under the conductive layer;
a signal line disposed under the conductive layer and electrically connected to the connection pad; and
a protective layer disposed under the conductive layer and having a lower surface positioned in a same plane as a lower surface of the connection pad.

2. The circuit board of claim 1, wherein a thickness of the protective layer is equal to a thickness of the connection pad.

3. The circuit board of claim 1, wherein the conductive layer includes:
a first conductive layer disposed on the connection pad and the signal line; and
a second conductive layer disposed on the first conductive layer.

4. The circuit board of claim 3, wherein the plurality of insulating layers include a first insulating layer disposed between the first conductive layer and the connection pad,
the connection pad is connected to the first conductive layer through at least one first contact hole penetrating the first insulating layer, and
the signal line is connected to the first conductive layer through at least one second contact hole penetrating the first insulating layer.

5. The circuit board of claim 4, wherein the first conductive layer includes a plurality of conductive patterns each extending in a first direction and spaced apart from each other in a second direction crossing the first direction, and
wherein the second conductive layer has a plate shape.

6. The circuit board of claim 5, wherein the connection pad and the signal line are spaced apart from each other in the first direction, and
wherein each of the conductive patterns overlaps the connection pad and the signal line in a plan view.

7. The circuit board of claim 4, wherein each of the first contact hole and the second contact hole has a polygonal cross-sectional shape.

8. The circuit board of claim 1, wherein the conductive layer includes:
a first conductive layer disposed on the connection pad and the signal line;
a second conductive layer disposed on the first conductive layer; and
a third conductive layer disposed on the second conductive layer.

9. The circuit board of claim 8, wherein the plurality of insulating layers include a first insulating layer disposed between the first conductive layer and the connection pad and a second insulating layer disposed on the first insulating layer, wherein
the connection pad is connected to the first conductive layer through at least one first contact hole penetrating the first insulating layer,
the signal line is connected to the first conductive layer through at least one second contact hole penetrating the first insulating layer, and
the second conductive layer is connected to the first conductive layer through at least one third contact hole and at least one fourth contact hole penetrating the second insulating layer.

10. The circuit board of claim 9, wherein each of the first and second conductive layers includes a plurality of conductive patterns each extending in a first direction and spaced apart from each other in a second direction crossing the first direction, and
wherein the third conductive layer has a plate shape.

11. The circuit board of claim 1, wherein the signal line is disposed on the protective layer and wherein the signal line is integral with the connection pad.

12. The circuit board of claim 11, wherein a thickness of a part of the signal line overlapping the protective layer is smaller than a thickness of the connection pad.

13. The circuit board of claim 1, wherein the protective layer includes a solder resist.

14. The circuit board of claim 1, wherein each of the connection pad, the signal line, and the conductive layer includes copper (Cu).

15. A display device comprising:
a substrate including a display area in which a plurality of pixels are arranged and a pad area spaced apart from one side of the display area;
a pad electrode disposed in the pad area on the substrate; and
a circuit board including:
a plurality of insulating layers;
at least one conductive layer disposed between the plurality of insulating layers;
a connection pad disposed under the conductive layer and connected to the pad electrode through an adhesive layer;
a signal line disposed under the conductive layer and electrically connected to the connection pad; and
a protective layer disposed under the conductive layer, overlapping at least a part of the pad area, and having a lower surface positioned in a same plane as a lower surface of the connection pad.

16. The display device of claim 15, wherein a thickness of the protective layer is equal to a thickness of the connection pad.

17. The display device of claim 15, wherein the conductive layer includes:
a first conductive layer disposed on the connection pad and the signal line; and
a second conductive layer disposed on the first conductive layer.

18. The display device of claim 17, wherein the plurality of insulating layers include a first insulating layer disposed between the first conductive layer and the connection pad,
the connection pad is connected to the first conductive layer through at least one first contact hole penetrating the first insulating layer, and
the signal line is connected to the first conductive layer through at least one second contact hole penetrating the first insulating layer.

19. The display device of claim 18, wherein the first conductive layer includes a plurality of conductive patterns each extending in a first direction and spaced apart from each other in a second direction crossing the first direction, wherein
the second conductive layer has a plate shape,
the connection pad and the signal line are spaced apart from each other in the first direction, and
each of the conductive patterns overlaps the connection pad and the signal line in a plan view.

20. The display device of claim 15, wherein the signal line is disposed on the protective layer and the signal line is integral with the connection pad, and
wherein a thickness of a part of the signal line overlapping the protective layer is smaller than a thickness of the connection pad.
